(19) United States
(12) Patent Application Publication
(10) Pub. No.: US 2014/0369884 A1
(43) Pub. Date: Dec. 18, 2014

(54) AG ALLOY FILM TO BE USED AS REFLECTING FILM AND/OR TRANSMITTING FILM OR AS ELECTRICAL WIRING AND/OR ELECTRODE, AG ALLOY SPUTTERING TARGET, AND AG ALLOY FILLER

(71) Applicant: KABUSHIKI KAISHA KOBE SEIKO SHO (Kobe Steel, Ltd.), Kobe-shi, Hyogo (JP)

(72) Inventors: Yuki Tauchi, Kobe-shi (JP); Yoko Shida, Kobe-shi (JP); Hiroyuki Okuno, Kobe-shi (JP)

(73) Assignee: KABUSHIKI KAISHA KOBE SEIKO SHO (Kobe Steel, Ltd.), Kobe-shi (JP)

(21) Appl. No.: 14/370,153

(22) PCT Filed: Jan. 22, 2013
(86) PCT No.: PCT/JP2013/051152

§ 371 Date: Jul. 1, 2014

(30) Foreign Application Priority Data
Feb. 2, 2012 (JP) 2012-021158
Aug. 1, 2012 (JP) 2012-171487

(51) Int. Cl. C22C 5/06; G02B 5/26; H01B 1/02; C23C 14/34; C23C 14/16

(52) U.S. Cl. CPC C22C 5/06; C23C 14/3414; C23C 14/165; H01B 1/023; G02B 5/26
USPC 420/503; 204/298.13; 420/505

(57) ABSTRACT

The present invention provides an Ag alloy film which exhibits a low-level electrical resistivity nearly equivalent to that of a pure Ag film and which is superior to a conventional Ag alloy film in durability (specifically, resistances to salt water and halogen) and in the adhesion to a substrate. Further, the deposition rate of this Ag alloy film by sputtering is as high as that of a pure Ag film. Provided is an Ag alloy film useful as a reflecting film and/or a transmitting film or as an electrical wiring and/or an electrode, including 0.1 to 1.5 atomic % of at least one element selected from Pd, Au and Pt, and 0.02 to 1.5 atomic % of at least one element selected from at least one rare earth element, Bi and Zn with the balance being Ag and inevitable impurities.

### TECHNICAL FIELD

The present invention relates to an Ag alloy film for use in a reflecting film and/or a transmitting film or as an electrical interconnection and/or an electrode, as well as an Ag alloy sputtering target and an Ag alloy filler for use in depositing the Ag alloy film. Specifically, the present invention relates to an Ag alloy film having low electrical resistivity that is almost at the same levels as that of a pure Ag film, and having excellent resistance to salt water or the like, and also having a deposition rate almost as high as that of a pure Ag film when the Ag alloy film is deposited preferably by sputtering.

### BACKGROUND ART

Since an Ag film of certain thickness or larger has high reflectance in visible light and low electrical resistance, it is expected to applicable to a reflective film including a reflective electrode and a transparent film including a transparent electrode of a thin-film transistor (TFT) substrate for an electronic device used for a display panel, an interconnection and an electrode in a touch-panel sensor, a solar cell panel, and a light emitting display device or the like, as well as a lighting device, an electromagnetic wave absorber, an antistatic film, or the like.

The reflectance of a pure Ag film, however, decreases due to generation of cloudiness when Ag reacts with a halogen element such as chlorine, or it is subjected to a heat treatment at about 100° C., or to a high temperature and high humidity environment. Moreover, adhesion of a pure Ag film to a substrate is, irrespective of substrate material, inferior to Al-based films that have been widely used for an interconnection material.

Followings are examples of technologies which improved the heat resistance and environment resistance of the Ag alloy films.

Patent Document 1 discloses an Ag alloy film containing one or two kinds of element selected from the group consisting of Bi and Sb in a total amount of 0.01 to 4 atomic %, which has high reflectance inherent in Ag and circumvents degradation of the reflectance with time by suppressing agglomeration and crystal grain growth.

Patent Document 2 discloses a silver alloy material containing at least one element selected from the group consisting of tin, zinc, lead, bismuth, indium, and gallium. An interconnection and/or an electrode comprising the silver alloy material possesses low electrical resistance, excellent heat resistance, and strong adhesion to a glass substrate as well as high plasma resistance and good light reflectance.

Patent Document 3 discloses an Ag alloy film of improved in a corrosion resistance, particularly a halogen resistance, an acid resistance and a sulfurization resistance. The Ag alloy is constituted of Ag with at least one metal component (A) selected from 0.05 to 2.0 mass % of In and 0.05 to 2.0 mass % of Sn in an amount of 0.05 to 2.0 mass % in total, and at least one metal component (B) selected from 0.1 to 4.9 mass % of Pd and 0.1 to 0.9 mass % of Pt in an amount of 0.1 to 4.9 mass % in total, and in which the total content of the metal component (A) and the metal component (B) is 0.2 to 5.0 mass %.

Patent Document 4 discloses an interconnection film, for forming interconnection lines of a flat panel display, formed of an Ag-base alloy containing 0.1 to 1.5 at % Nd and Ag as the remainder. Specifically, the Document discloses improved micro-fabrication property and low electrical resistivity by addition of Nd to Ag. Also disclosed is improved heat resistance by suppression of surface roughness due to aggregation of Ag even when the film is subjected to heating to high temperatures.

However, when the Ag alloy film is used for an interconnection or an electrode of, for example, a touch-panel sensor, above-described cloudiness is liable to be generated due to difference in use environment of the device.

As the Ag alloy film is preferably deposited by sputtering, an Ag alloy film having high sputtering deposition rate, excellent durability without the cloudiness is desired from the viewpoint of productivity.

### PRIOR ART REFERENCES

### Patent Documents

Patent Document 1: Japanese Patent Application Publication No. 2004-126497
Patent Document 2: Japanese Patent Application Publication No. 2005-054268
Patent Document 3: Japanese Patent No. 3855958
Patent Document 4: Japanese Patent Application Publication No. 2005-187937

### SUMMARY OF THE INVENTION

### Problems to be Solved by the Invention

The present invention has been made in light of the circumstances described above. It is an object of the present invention to provide an Ag alloy film for use in a reflecting film and/or a transmitting film or as an electrical interconnection and/or an electrode, as well as an Ag alloy sputtering target and an Ag alloy filler for use in depositing the Ag alloy film. The Ag alloy film exhibits a low-level electrical resistivity that is necessary for an interconnection and is nearly equivalent to that of a pure Ag film. The Ag alloy film also is superior to a conventional Ag alloy film in durability (specifically, resistances to salt water and halogen) and in the adhesion to a substrate. Further, the deposition rate of this Ag alloy film by sputtering is as high as that of a pure Ag film.

### Solution to Problem

The present invention, which solves the problem, relates to an Ag alloy film for use in a reflecting film and/or a transmitting film or as an electrical interconnection and/or an electrode, comprising 0.1 to 1.5 atomic % of at least one element selected from the group consisting of Pd, Au and Pt; 0.02 to 1.5 atomic % of at least one element selected from the group consisting of at least one rare earth element, Bi and Zn; with the balance being Ag and inevitable impurities.

The rare earth element is at least one element selected from the group consisting of Nd, La, Gd, and Ce in a preferred embodiment.

The Ag alloy film further comprises at least one element selected from the group consisting of Mg, Cu, Zn, Ge, In, and Ca in an amount of 0.1 to 2.0 atomic % in a preferred embodiment.

The Ag alloy sputtering target of the present invention which solved the problem is, for use in depositing the Ag alloy film, comprising; 0.1 to 1.5 atomic % of at least one element selected from the group consisting of Pd, Au and Pt; 0.02 to 1.5 atomic % of at least one element selected from the group consisting of at least one rare earth element, Bi and Zn; with the balance being Ag and inevitable impurities.

The rare earth element is at least one element selected from the group consisting of Nd, La, Gd, and Ce in a preferred embodiment.

The Ag alloy sputtering target further comprises at least one element selected from the group consisting of Mg, Cu, Zn, Ge, In, and Ca in an amount of 0.1 to 2.0 atomic % in a preferred embodiment.

The Ag alloy filler of the present invention which solved the problem is, for use in depositing the Ag alloy film, comprising; 0.1 to 1.5 atomic % of at least one element selected from the group consisting of Pd, Au and Pt, 0.02 to 1.5 atomic % of at least one element selected from the group consisting of at least one rare earth element, Bi and Zn; with the balance being Ag and inevitable impurities.

The rare earth element is at least one element selected from the group consisting of Nd, La, Gd, and Ce in a preferred embodiment.

The Ag alloy filler further comprises at least one element selected from the group consisting of Mg, Cu, Zn, Ge, In, and Ca in an amount of 0.1 to 2.0 atomic % in a preferred embodiment.

The Ag alloy filler comprises an Ag alloy nanoparticle in a preferred embodiment.

The present invention also encompasses a variety of product comprising the Al alloy film, including for example, a reflective electrode or a transparent electrode; a display device such as an organic EL display and an inorganic EL display; a lighting device; electronic devices such as an input device, a touch-panel sensor, a wiring substrate, a film type cable, a film type antenna, and a solar cell panel; as well as an electromagnetic wave absorber, an antistatic film, a light attenuation film, and a heat insulation film.

### Advantageous Effects of Invention

According to the present invention, provided is an Ag alloy film having a low-level electrical resistivity that is nearly equivalent to that of a pure Ag film, also having durability that is superior to a conventional Ag alloy film as well as excellent adhesion to a substrate. Further, the Ag alloy film is superior in productivity because the deposition rate is as high as that of a pure Ag film when the Ag alloy film is deposited preferably by sputtering. The Ag alloy film of the present invention is useful for a reflecting film and/or a transmitting film or as an electrical interconnection and/or an electrode, as well as for a variety of their applications. For example, the Ag alloy film exhibits the excellent properties when it is applied to an interconnection or an electrode for a touch-panel sensor or the like.

### DESCRIPTION OF EMBODIMENTS

The present inventors made intensive studies aiming to provide an Ag alloy film having a low-level electrical resistivity and a high sputtering deposition rate that are nearly equivalent to those of a pure Ag film, also having durability (specifically, resistances to salt water and halogen) that is superior to a conventional Ag alloy film as well as excellent adhesion to a substrate, even when it is applied to a reflecting film and/or a transmitting film or as an electrical interconnection and/or an electrode of, for example, a touch-panel sensor in which the durability is liable to be deteriorated because of its use environment.

It has been found as a result of the research that an Ag alloy film comprising a combination of; at least one kind of element (sometimes represented as X group element) selected from the group (sometimes referred to X group) consisting of Pd, Au and Pt; at least one element (sometimes represented as Z group element) selected from the group (sometimes referred to Z group) consisting of at least one rare earth element, Bi and Zn; in which contained amount of each element is appropriately regulated, exhibits a low-level electrical resistivity and a sputtering deposition rate that are nearly equivalent to those of a pure Ag film, as well as durability and adhesion to a substrate that are far superior to a conventional Ag alloy film.

The Ag alloy film of the present invention is thus expressed as Ag—X group element —Z group element alloy film. The Ag alloy film shows not only low electrical resistivity and high sputtering deposition rate that are nearly equivalent to those of a pure Ag film, but also superior durability (specifically, resistances to salt water and halogen). Moreover, as the Ag alloy film is excellent in terms of adhesion to a substrate, it enables to improve the properties without the sacrifice of productivity. It is thus exceptionally useful. As demonstrated by Examples described below, Ag alloy containing only either an X group element or a Z group element does not satisfy all of the properties. It was also found that the desired properties cannot be obtained if an Ag alloy film contains an element other than those (the X group and Z group elements) specified by the present invention.

Hereinbelow, each of elements constituting the Ag alloy film of the present invention is explained.

The X group element is at least one element selected from the group consisting of Pd, Au and Pt. Each of these elements contributes to improvements of mainly resistances to salt water and halogen, and further of adhesion to a substrate. As shown in Examples described below, specimens without an X group element are inferior in terms of these properties. The X group elements may be added solely to the alloy. Two or more kinds of the X group elements may also be added to the alloy. Preferred X group elements are Au and Pd. More preferred X group element is Pd.

To effectively provide the effect, the contained amount of the X group element is to be controlled to 0.1 atomic % or more. If one kind of element is contained, the amount means solo amount. If one kind of the X group element is contained, the amount means its solo amount. If more than one kind of the X group elements are contained, the amount means their total amount hereinbelow. From the viewpoint of improving the durability, the more the contained amount of the X group element, the more preferable. The contained amount of the Z group element is preferably 0.3 atomic % or more. Upper limit of the amount of the X group element is not particularly limited from the viewpoint of improving the properties. However, an excessive amount of the X group element is liable to result in increase of the electrical resistivity. Moreover, the group X elements are noble metals of high cost. As such, the contained amount is to be appropriately controlled considering the production cost. It is noted specifically that the effect of the X group elements to electrical resistivity is lower than that of the Z group elements as described below. On the other hand, as an excessive amount of the X group element is liable to cause increasing the electrical resistivity, the amount is preferably set to be 1.5 atomic % or less, and more preferably 1.0 atomic % or less.

The Z group element is at least one kind of element selected from the group consisting of at least one rare earth element (REM), Bi and Zn, which are mainly contributing to improvement of adhesion to a substrate and sputtering deposition rate. As demonstrated by Examples described below, an Ag alloy containing only either an X group element or a Z group element does not satisfy all of the properties. As demonstrated in Example described below, an Ag alloy without a Z group element is inferior in terms of adhesion to a substrate and sputtering deposition rate. In order to effectively provide the effect of improving the adhesion to a substrate, it is necessary to add a Z group element in a combination with a X group element. Solely adding a Z group element without an X group element is not effective to obtain a desirable effect. A Z group element may be used alone or in combination of two or more. Among the Z group elements, Nd, Gd, and La are preferred, and Nd is more preferred.

Here, the rare-earth metal (REM) indicates an element group including Sc (scandium) and Y (yttrium) in addition to lanthanoid elements (a total of 15 elements from La to Lu in the periodic table). In the present invention, the rare-earth elements may be used alone or in combination of two or more. If one kind of REM is contained, the amount means its solo amount. If more than one kind of REM are contained, the amount means their total amount. Among the rare-earth elements, Nd, La, Gd, and Ce are preferred.

To effectively provide the effect of the Z group element, the contained amount of the Z group element (when one of the elements is added, the amount is based on the amount of the element contained; and when two or more of the elements are added, the amount is based on the total amount of the elements) is preferably in the range of 0.02 atomic % or more. From the viewpoint of improving the properties, the more the contained amount of the Z group element, the more preferable. The contained amount of the Z group element is preferably 0.05 atomic % or more, more preferably 0.1 atomic % or more, and even more preferably 0.15 atomic % or more. Upper limit of the amount of the Z group element is not particularly limited from the viewpoint of improving the properties. However, as an excessive amount of the Z group element increases the electrical resistivity, it is set to be 1.5 atomic % or less. The contained amount of the Z element is preferably 1.0 atomic % or less, more preferably 0.7 atomic % or less, and even more preferably 0.5 atomic % or less.

Examples of preferred combination of the Ag—X group element —Z group element alloy films of the present invention are; Ag—Pd—Nd, Ag—Pd—La, and Ag—Au—Nd.

Chemical compositions of the Ag alloy film of the present invention are as explained above. The remainder is made of Ag and inevitable impurities.

Further, in addition to the foregoing elements, an appropriate amount of at least one kind of element selected from a group consisting of Mg, Cu, Zn, Ge, In, and Ca, may further be contained. Mg, Cu, Zn, Ge, In, and Ca are elements which exert an effect to enhance durability further. To effectively provide the effect, the contained amount of these elements (when one of the elements is added, the amount is based on the amount of the element contained; and when two or more of the elements are added, the amount is based on the total amount of the elements) is preferably to be 0.1 atomic % or more, and more preferably 0.3 atomic % or more. On the other hand, as an excessive amount of these elements increases the electrical resistivity, the amount is preferably set to be 2.0 atomic % or less, and more preferably 1.0 atomic % or less.

Thickness of the Ag alloy film is preferably in a range of 50 to 500 nm. By setting the thickness to 50 nm or more, it is possible to suppress the interconnecting resistance and to further enhance the durability. The preferred thickness is 150 nm or more. On the other hand, as an excessive thickness deteriorates the form of the interconnection and the micro-fabrication property, the thickness is preferably set to be 500 nm or less, and more preferably 400 nm or less.

A substrate used for the present invention is not particularly limited. Examples of such substrate are glass, resin such as PET (polyethylene terephthalate), or the like. The Ag alloy film of the present invention exhibits favorable adhesion to these kinds of substrates.

The Ag alloy film is preferably formed by a sputtering method with a sputtering target (hereinafter, also referred to as a “target”) or an Ag alloy filler, preferably comprising an Ag alloy nanoparticle. The sputtering is preferred because a thin film having excellent in-plane uniformity in components and thickness can be easily formed, as compared with the cases where a thin film is formed by an ink-jet method or a vacuum evaporation method. An ink-jet method using a dispersed liquid containing an Ag alloy filler, preferably comprising an Ag alloy nanoparticle, is also preferred because of its excellent productivity.

When the Ag alloy film is deposited by the sputtering method, an Ag alloy sputtering target containing the X group element and the Z group element in each of the predetermined amount is useful. Basically, these elements contained in the Ag alloy sputtering target may be controlled in substantially same amounts as those in the Ag alloy film without compositional deviation. However, Bi is an element which is liable to be concentrated in the vicinity of the surface of the Ag alloy film, and therefore, it is preferable that the sputtering target contains Bi in an amount of about 5 times the Bi amount in the Ag alloy film.

Examples of a method for producing the target include a vacuum melt-casting method and a powder sintering method. The vacuum melt-casting method is preferred from a view point of securing in-plane uniformity in composition and texture of target.

The Ag alloy filler, preferably consisting of Ag alloy nanoparticles, may be prepared by, for example, a wet-milling method, a dry-milling method, and atomization by vaporization.

The Ag alloy film according to the present invention satisfies the property of electrical resistivity of 6.0 μΩcm or less. The electrical resistivity is preferably 5.5 μΩcm or less, more preferably 5.0 μΩcm or less, and even more preferably 4.0 μΩcm or less.

Since an Ag film of the present invention has high durability as well as intrinsic properties such as high reflectance and electrical resistivity low of an Ag alloy, it is suitably used for a variety of applications such as typically a reflective film (a reflective electrode), a transparent film (a transparent electrode), an interconnection and an electrode of an electronic device. It is also useful for example a lighting device; a reflective film and/or a transparent film in an input device; a display device such as an organic EL display and an inorganic EL display; a touch-panel sensor; a wiring substrate in a FPR, a RF-ID tag, a cellular phone, a car navigation system, or the like; a flexible wiring substrate; a film cable; a film antenna; an interconnection and an electrode of a solar cell panel, an electromagnetic wave absorber, an antistatic film, and a heat insulation film.

### EXAMPLES

The present invention is more specifically described below by presenting examples. The present invention is not limited to these examples described below. The present invention may be modified and performed without departing from the essence of the present invention described above and below. They are also within the technical scope of the present invention.

On a glass substrate (an alkali-free glass # 1737 manufactured by Corning Inc., diameter: 50 mm, thickness: 0.7 mm) pure Ag or Ag alloy films having various alloy compositions shown in Table 1 were deposited by sputtering method using a DC magnetron sputtering apparatus. The deposition condition was as follows.

### (Film Deposition Condition)

Substrate temperature: room temperature

Sputtering power: 15 W-dc/cm²

Ar gas pressure: 1-3 mTorr

Anode-cathode distance: 55 mm

Deposition rate: 7.0-8.0 nm/sec

Base pressure: 1.0×10⁻⁵ Torr or less

A pure Ag target was used to deposit the pure Ag film. Used to deposit the Ag alloy films were Ag alloy sputtering targets prepared by a vacuum melt-casting method having the same composition as each of the films shown in Table 1. The diameter of each of the target was 4 inches. An Ag alloy sputtering target comprising Bi of about five times of that in the film was used to deposit the film of No. 18 in Table 1.

Measurements were conducted for the pure Ag and Al alloy films prepared by the foregoing method in terms of durability (resistances to salt water and halogen), adhesion to a substrate, electrical resistivity, and absorption factor of the visible light at a wavelength of 450 nm. The details of the measurement methods are as follows.

Chemical compositions of the Ag alloy films used in the examples were quantitatively measured by using an inductively coupled plasma emission spectrometer (ICP-8000 manufactured by Shimadzu Corporation). This is the same for Example 2 described below.

### (Salt Water Test: Evaluation of Durability (Resistances to Salt Water and Halogen))

Each sample comprising an Ag or Al alloy film on a substrate was subjected to a test of immersing the sample in a 5 weight % aqueous sodium chloride solution (25° C.) for 3 hours. After rinse in deionized water followed by drying, the Ag or Al alloy films were visually inspected to evaluate the degree of cloudiness. Samples in which the cloudiness was not observed were rated as “none” (high durability) and samples which show the cloudiness to a certain extent were rated “light”, and samples which exhibit a significant degree of cloudiness was rated “severe” (poor durability).

### (Adhesion Evaluation Test)

Adhesion performance of the films was evaluated by a tape peeling test. Specifically, slits were formed on the surface of a deposited pure Ag or Ag alloy film with a cutter knife so as to form a grid at intervals of 1 mm. Successively, an adhesive tape (Scotch™ 600, manufactured by Sumitomo 3M Limited) was put on the film and peeled off at a stroke while the peeling off angle of the adhesive tape was kept at 60 degrees. The number of the segments peeled off by the adhesive tape in the grid was counted, and the ratio of the number to the total number of the segment (a peel off rate) was obtained. The test was conducted three times for each specimen, and the mean value of which was regarded as the “peel off rate”. In the evaluation of the test, a case where the peel off rate is 25% or less is judged as good (good adhesion to a substrate) and a case where the peel off rate is more than 25% is judged as poor (poor adhesion to a substrate).

### (Measurement of Electrical Resistivity)

Electrical resistivity of the pure Ag film or the Ag alloy film was measured by the four probe method. In the evaluation of the test, a case where the electrical resistivity is 6.0 μΩcm or lower was judged as low electrical resistivity. The results are summarized in Table 1.

TABLE 1

| | | Breakdown of chemical | | | | | |
|---|---|---|---|---|---|---|---|
| | | composition | | | cloudiness | Adhesion | Electrical |
| | | X group | Z group | Other | after salt | to | resistivity |
| No. | Chemical composition* | element | element | element | water test | substrate | [μΩcm] |
| 1 | Ag | — | — | — | severe | poor | 2.8 |
| 2 | Ag—0.05Nd—0.1Pd | 0.1Pd | 0.05Nd | — | light | good | 3 |
| 3 | Ag—0.1Nd—0.2Pd | 0.2Pd | 0.1Nd | — | none | good | 3.2 |
| 4 | Ag—0.15Nd—0.3Pd | 0.3Pd | 0.15Nd | — | none | good | 3.4 |
| 5 | Ag—0.25Nd—0.5Pd | 0.5Pd | 0.25Nd | — | none | good | 4.1 |
| 6 | Ag—0.35Nd—0.7Pd | 0.7Pd | 0.35Nd | — | none | good | 4.4 |
| 7 | Ag—0.5Nd—1.0Pd | 1.0Pd | 0.5Nd | — | none | good | 5.1 |
| 8 | Ag—0.7Nd—1.4Pd | 1.4Pd | 0.7Nd | — | none | good | 6 |
| 9 | Ag—0.5La—1.0Pd | 1.0Pd | 0.5La | — | none | good | 5.2 |
| 10 | Ag—0.5Gd—1.0Pd | 1.0Pd | 0.5Gd | — | none | good | 5.1 |
| 11 | Ag—0.5Ce—1.0Pd | 1.0Pd | 0.5Ce | — | none | good | 5.2 |
| 12 | Ag—0.25Nd—0.25La—1.0Pd | 1.0Pd | 0.25Nd—0.25La | — | none | good | 5.1 |
| 13 | Ag—0.25Nd—0.25Gd—1.0Pd | 1.0Pd | 0.25Nd—0.25Gd | — | none | good | 5.1 |
| 14 | Ag—0.5Nd—1.0Au | 1.0Au | 0.5Nd | — | none | good | 5.2 |
| 15 | Ag—0.5Nd—1.0Pt | 1.0Pt | 0.5Nd | — | none | good | 5.1 |
| 16 | Ag—1.0In | — | — | 1.0In | severe | good | 4.3 |
| 17 | Ag—0.5Nd—1.0Cu | — | 0.5Nd | 1.0Cu | severe | poor | 5 |
| 18 | Ag—0.5Nd—1.0Bi | — | 0.5Nd—1.0Bi | — | severe | poor | 5.1 |
| 19 | Ag—1.0Pd—1.0Cu | 1.0Pd | — | 1.0Cu | none | poor | 3.2 |

*Unit of numerical values is atomic %.

The results shown in Table 1 can be understood as follows.

It was confirmed that the Ag—X group element —Z group element alloy films of Nos. 2 to 15 comprising at least one X group element selected from the group consisting of Pd, Au and Pt, and at least one Z group element selected from the group consisting of at least one rare earth element, Bi, and Zn, as specified in the present invention, are excellent in terms of salt water resistance as demonstrated by the suppressed cloudiness after the salt water test, as well as having good adhesion to the substrate and low electrical resistivity.

On the other hand, significant cloudiness was observed on a pure Ag film (No. 1) which did not secure adhesion to the substrate.

The Ag alloy film of sample No. 16 is a comparative example containing In, an element other than the X group and the Z group elements specified in the present invention, which showed significant cloudiness after the salt water test as for the pure Ag film even though the adhesion to the substrate was good.

The Ag alloy film of sample No. 17 is a comparative example containing a Z group element but an X group element. Instead, the sample contains Cu which is not an essential element in the present invention. It showed significant cloudiness after the salt water test and poor adhesion to the substrate. From the result, it was confirmed necessary to contain both an X group element and a Z group element in order to improve the adhesion to the substrate. It was also indicated that Cu negatively affects adhesion to the substrate.

The Ag alloy film of sample No. 18 is a comparative example containing an X group element but a Z group element, which showed significant cloudiness after the salt water test and poor adhesion to the substrate. As for the sample No. 17, it was confirmed necessary to contain both an X group element and a Z group element in order to improve the adhesion to the substrate.

The Ag alloy film of sample No. 19 is a comparative example containing an X group element but a Z group element. Instead, the sample contains Cu which is not an essential element in the present invention. It showed significant cloudiness after the salt water test and poor adhesion to the substrate. As for the results of the samples No. 17 and 18, it was confirmed necessary to contain both an X group element and a Z group element in order to improve the adhesion to the substrate.

### EXAMPLE 2

On a glass substrate (an alkali-free glass # 1737 manufactured by Corning Inc., diameter: 50 mm, thickness: 0.7 mm) pure Ag or Ag alloy films having various alloy compositions shown in Table 2 were deposited by sputtering method using a DC magnetron sputtering apparatus. The films were in the form of a single layer of 100 nm in thickness. The deposition condition was as follows.

### (Film Deposition Condition)

Substrate temperature: room temperature

Sputtering power: 2.55 W-dc/cm²

Ar gas pressure: 1.9 Pa

Anode-cathode distance: 120 mm

Base pressure: 4.0×10⁻⁵ Torr or less

A pure Ag target was used to deposit the pure Ag film. Used to deposit the Ag alloy films were Ag alloy sputtering targets prepared by a vacuum melt-casting method having the same composition as each of the films shown in Table 2. The diameter of each of the target was 4 inches. An Ag alloy sputtering target comprising Bi of about five times of that in the film was used to deposit the films of Nos. 15 to 17 and 22 in Table 2.

The pure Ag and Al alloy films prepared by the foregoing method were evaluated in terms of durability (resistances to salt water and halogen) and sputtering deposition rate. The details of the measurement method are shown below.

### (Deposition Rate by Sputtering)

The pure Ag or Ag alloy film deposited by the above-described method was measured for thickness with a stylus step gauge (“Alpha-Step” available from KLA-Tencor Instruments). The measurement of thickness was carried out at three sites in total taken in an interval of 5 mm from the center of the thin film toward the radius direction of the thin film, the mean value of which was regarded as the “thin film thickness” (nm). The “thin film thickness” thus measured was divided by sputtering time (minute) for the calculation of mean deposition rate (nm/minute).

In the present Example, the deposition rate ratio to pure Ag (=mean deposition rate of each of Ag alloy film/mean deposition rate of pure Ag) was calculated using a mean deposition rate of a film obtained by using a pure Ag sputtering target as a standard. Higher deposition rate ratios to pure Ag thus calculated mean higher deposition rates. In the present Example, the Ag alloys were evaluated as high sputtering deposition rate when the deposition rate ratio to pure Ag was 0.90 or more.

The results are summarized in Table 2.

TABLE 2

| | | Breakdown of chemical | | | | |
|---|---|---|---|---|---|---|
| | | composition | | | cloudiness | |
| | | X group | Z group | Other | after salt | Deposition rate |
| No. | Chemical composition* | element | element | element | water test | (ratio to pure Ag) |
| 1 | Ag | — | — | — | severe | 1.00 |
| 2 | Ag—0.05Nd—0.1Pd | 0.1Pd | 0.05Nd | — | light | 0.99 |
| 3 | Ag—0.1Nd—0.2Pd | 0.2Pd | 0.1Nd | — | none | 0.98 |
| 4 | Ag—0.2Nd—0.3Pd | 0.3Pd | 0.2Nd | — | none | 1.00 |
| 5 | Ag—0.25Nd—0.5Pd | 0.5Pd | 0.25Nd | — | none | 0.99 |
| 6 | Ag—0.35Nd—0.7Pd | 0.7Pd | 0.35Nd | — | none | 0.95 |
| 7 | Ag—0.5Nd—1.0Pd | 1.0Pd | 0.5Nd | — | none | 0.90 |
| 8 | Ag—0.7Nd—1.4Pd | 1.4Pd | 0.7Nd | — | none | 0.92 |
| 9 | Ag—0.5La—1.0Pd | 1.0Pd | 0.5La | — | none | 0.91 |
| 10 | Ag—0.5Gd—1.0Pd | 1.0Pd | 0.5Gd | — | none | 0.91 |
| 11 | Ag—0.25Nd—0.25La—1.0Pd | 1.0Pd | 0.25Nd—0.25La | — | none | 0.91 |
| 12 | Ag—0.25Nd—0.25Gd—1.0Pd | 1.0Pd | 0.25Nd—0.25Gd | — | none | 0.91 |
| 13 | Ag—0.5Nd—1.0Au | 1.0Au | 0.5Nd | — | none | 0.90 |
| 14 | Ag—0.5Nd—1.0Pt | 1.0Pt | 0.5Nd | — | none | 0.91 |
| 15 | Ag—0.85Bi—1.0Pd | 1.0Pd | 0.85Bi | — | none | 0.93 |
| 16 | Ag—0.85Bi—1.0Au | 1.0Au | 0.85Bi | — | none | 0.92 |
| 17 | Ag—0.85Bi—1.0Pt | 1.0Pt | 0.85Bi | — | none | 0.91 |
| 18 | Ag—1.3Zn—0.5Pt | 0.5Pt | 1.3Zn | — | none | 0.93 |
| 19 | Ag—1.3Zn—0.5Pt | 0.5Pt | 1.3Zn | — | none | 0.93 |
| 20 | Ag—1.3Zn—0.5Pt | 0.5Pt | 1.3Zn | — | none | 0.91 |
| 21 | Ag—1.0Pd | 1.0Pd | — | — | none | 0.87 |
| 22 | Ag—1.0Bi | — | 1.0Bi | — | severe | 0.92 |
| 23 | Ag—0.5Nd | — | 0.5Nd | — | severe | 1.21 |
| 24 | Ag—0.7Nd—0.9Cu | — | 0.7Nd | 0.9Cu | severe | 0.84 |
| 25 | Ag—1.0Pd—1.0Cu | 1.0Pd | — | 1.0Cu | none | 0.75 |
| 26 | Ag—1.0Au—0.9Cu | 1.0Au | — | 0.9Cu | none | 0.87 |

*Unit of numerical values is atomic %.

The results shown in Table 2 can be understood as follows.

It was confirmed that the Ag—X group element —Z group element alloy films of Nos. 2 to 20 comprising at least one X group element selected from the group consisting of Pd, Au and Pt, and at least one Z group element selected from the group consisting of at least one rare earth element, Bi, and Zn, as specified in the present invention, were excellent in terms of salt water resistance as demonstrated by the suppressed cloudiness after the salt water test, and that the deposition rate was almost as high as that of a pure Ag film.

The pure Ag film of example No.1, on the other hand, showed severe cloudiness due to the salt water test while the deposition rate was high.

It was found that the Ag alloy film of example No. 21 containing only an X group element without a Z group element showed remarkable decrease in the deposition rate even though the cloudiness after the salt water test was suppressed.

It was found, on the other hand, that the Ag alloy films of sample Nos. 22 and 23 containing only a Z group element without a X group element showed remarkable cloudiness after the salt water test even though the decrease in the deposition rate was suppressed.

From these results, it was confirmed necessary to contain both an X group element and a Z group element in order to satisfy the specified properties in the present invention.

It was found, on the other hand, that the Ag alloy film of sample No. 24 containing a Z group element and Cu, which is not an essential element in the present invention, but a X group element, showed significant cloudiness after the salt water test and a marked decrease in the deposition rate. The deposition rate was decreased in the sample in spite of the addition of Nd, a Z group element, in the specified amount. It is supposed because of excessive total amount of additional elements.

The Ag alloy films of sample Nos. 25 and 26 are comparative examples containing an X group element but a Z group element. Instead, the samples contained Cu which is not an essential element in the present invention. Although no cloudiness was observed after the salt water test, the samples showed a marked decrease in the deposition rate, failing to exhibit a high deposition rate intrinsic to Ag.

This application claims the benefit of priority to Japanese Patent Application Nos. 2012-021158 and 2012-171487 filed on Feb. 2, 2012 and Aug. 1, 2012, respectively. The entire contents of Japanese Patent Application Nos. 2012-021158 and 2012-171487 are incorporated by reference herein in their entirety.

1. An Ag alloy film formed on a substrate, used for a reflecting film and/or a transmitting film or as an electrical interconnection and/or an electrode, comprising;
at least one element selected from the group consisting of Pd, Au and Pt, in an amount of 0.1 to 1.5 atomic %,
at least one element selected from the group consisting of at least one rare earth element, Bi and Zn in an amount of 0.02 to 1.5 atomic %,
with the balance being Ag and inevitable impurities.

2. The Ag alloy thin film according to claim 1, wherein
the rare earth element is at least one element selected from the group consisting of Nd, La, Gd, and Ce.

3. The Ag alloy thin film according to claim 2, further comprising
at least one element selected from the group consisting of Mg, Cu, Zn, Ge, In, and Ca in an amount of 0.1 to 2.0 atomic %.

4. An Ag alloy sputtering target, for use in depositing the Ag alloy film according to one of claims 1 to 3, comprising;
at least one element selected from the group consisting of Pd, Au and Pt, in an amount of 0.1 to 1.5 atomic %,
at least one element selected from the group consisting of at least one rare earth element, Bi and Zn in an amount of 0.02 to 1.5 atomic %,
with the balance being Ag and inevitable impurities.

5. alloy sputtering target according to claim 4, wherein
the rare earth element is at least one element selected from the group consisting of Nd, La, Gd, and Ce.

6. The Ag alloy sputtering target according to claim 5, further comprising
at least one element selected from the group consisting of Mg, Cu, Zn, Ge, In, and Ca in an amount of 0.1 to 2.0 atomic %.

7. An Ag alloy filler, for use in forming the Ag alloy film according to one of claims 1 to 3, comprising;
at least one element selected from the group consisting of Pd, Au and Pt, in an amount of 0.1 to 1.5 atomic %,
at least one element selected from the group consisting of at least one rare earth element, Bi and Zn in an amount of 0.02 to 1.5 atomic %,
with the balance being Ag and inevitable impurities.

8. The Ag alloy filler according to claim 7, wherein
the rare earth element is at least one element selected from the group consisting of Nd, La, Gd, and Ce.

9. The Ag alloy filler according to claim 8, further comprising
at least one element selected from the group consisting of Mg, Cu, Zn, Ge, In, and Ca in an amount of 0.1 to 2.0 atomic %.

10. The Ag alloy filler according to claim 7, comprising an Ag alloy nanoparticle.

11. alloy filler according to claim 8, comprising an Ag alloy nanoparticle.

12. An electronic device comprising the Ag alloy film according to one of claims 1 to 3.

13. An electromagnetic wave absorber comprising the Ag alloy film according to one of claims 1 to 3.

14. An antistatic film comprising the Ag alloy film according to one of claims 1 to 3.

15. A light attenuation film or a heat insulation film comprising the Ag alloy film according to one of claims 1 to 3.
